(19) United States
(12) Patent Application Publication
(10) Pub. No.: US 2007/0189049 A1
(43) Pub. Date: Aug. 16, 2007

(54) Semiconductor memory module

(76) Inventors: Srdjan Djordjevic, Munchen (DE); Peter Oeschay, Wehringen (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/355,649

(22) Filed: Feb. 16, 2006

(51) Int. Cl. G11C 5/02

(52) U.S. Cl. 365/51

(57) ABSTRACT

A semiconductor memory module having a plurality of memory chips and at least one bus connecting the plurality of memory chips is provided. The bus has two branches, a first connected to a greater quantity of memory chips than a second branch.

### TECHNICAL FIELD

The present invention relates to semiconductor memory modules.

### BACKGROUND

Semiconductor memory modules usually comprise one or more memory chips arranged on a printed circuit board (PCB) that can be plugged into a memory slot of a computer mainboard.

In recent years there have been changes in semiconductor memory architecture and capacities (e.g., SD RAM (Single Data Random Access Memory) has evolved into DDR1 (Double Data Rate) RAM, which has further evolved into DDR2 RAM). Further enhancements, which will lead to, for instant, faster speed and lower costs, are already under development.

The development of memory modules has also diversified to different architectures of the memory chips. Memory modules with ECC (Error Correction Code) chips are available as well as memory modules equipped with a buffer chip (e.g. buffered or fully buffered DIMMs (Double Inline Memory Modules)).

At the same time there is also an increased demand for larger main memories. Because chipset restrictions cause a limit of available memory slots on the mainboard, there is an ongoing trend to increase the overall memory density of the memory modules.

A few solutions to address this issue have been stacked DIMMs, where DRAM (Dynamic Random Access Memory) chips are arranged in stacks on the module, or double height DIMMs, which have a printed circuit board of double height compared to standard memory modules.

But as modules are developed and improved, memory chips, particularly their capacity, are being improved as well. For example, DRAM Chips are available in sizes up to 256 Mb and 512 Mb, with sizes of 1 Gb being introduced. New DRAM chips usually have bigger dimensions than the older models, all of which requires a redesign of the memory module.

Based on the foregoing, there is a need for a more flexible approach regarding semiconductor memory modules.

### SUMMARY

The present invention is directed to a semiconductor memory module that satisfies the need for a more flexible approach. According to at least one embodiment of the present invention a semiconductor memory module has a plurality of memory chips and at least one bus connecting the plurality of memory chips. The bus has at least a first and second branch, wherein the first branch is connected to a greater quantity of memory chips than the second branch.

The present invention proposes to create a memory module having a command/address (C/A) bus architecture that is asymmetric. Here, asymmetric means the branches of the command/address bus have different loads (i.e., the memory chips). Asymmetric could also mean that the length of the branches is different.

This allows for new design rules concerning the placement of the chips on the module. According to the present invention it is further possible to design command/address buses avoiding a stub bus architecture in which a small part of the bus (e.g. connecting to the ECC Chips) is branching off the bus. The stubless design has improved signal integrity since reflections on the bus are reduced.

According to at least one embodiment of the present invention a branch is part of a bus which origins at one single point, e.g. a single pin of a hub chip or a single pin of a connection from the memory module to a computer system. The branches can branch off the bus at a junction of the connection, wherein the junction can be located away from the pin or directly at the pin.

The additional memory chips associated with, for instance, the first branch, as compared to the second branch, may be error correction code (ECC) chips.

A further embodiment of a memory module according to the present invention has a plurality of memory chips and at least one command/address (C/A) bus that connects to the plurality of memory chips. The command/address bus comprises two branches, wherein a first branch of the command/address bus connects to a greater quantity of memory chips than a second branch. The additional memory chips of the first branch compared to the second branch are error correction code chips.

According to a further embodiment of the present invention a semiconductor memory module comprises a printed circuit board that has a printed circuit board that has a top surface, a bottom surface and a central area. Each surface has a left part and a right part adjacent to the central area. The module further comprises a plurality of memory chips that are connected to the top and bottom surfaces, and are arranged in a lower row and an upper row. Each row comprises a left section and a right section. Error correction code chips are connected to the top and bottom surfaces in the central area. The module has at least one left command/address bus which is arranged at the at least one left section of the printed circuit board and connects to the memory chips disposed at the left sections. Further, the module comprises at least one right command/address bus which is arranged at the at least one right section of the printed circuit board and connects to the memory chips disposed at the right sections. At least one data connection is arranged at the at least one left section of the printed circuit board and connects to the memory chips disposed at the left sections and at least one data connection is arranged at the at least one right part of the printed circuit board and connects to the memory chips disposed at the right sections. A control chip is provided that drives command/address signals to the memory chips and/or the error correction code chips via the left and right command/address buses and that drives data signals to and receives them from the memory chips and/or the error correction code chips via the at least one data connection. The control chip is disposed in the central area. The command/address bus comprises a lower branch and an upper branch wherein the lower branch connects to the memory chips of the lower rows and the upper branch connects to the memory chips of the upper rows and to the error correction code chips of the respective section of the central part.

This embodiment of the invention introduces a new design of a memory module. In particular a novel configuration of the chips and connections on the memory module. With an asymmetric command/address bus it is possible to place the ECC Chips above the hub chip. This facilitates design and production of the memory module since the wiring can be distributed over a bigger area. Because the hub chip is not arranged on the opposite side of the ECC Chips no expensive blind vias are required.

In a further embodiment the present invention proposes a computer system which comprises a processor and a memory subsystem, including at least one of the semiconductor memory modules described previously.

According to a further embodiment of the present invention a method of manufacturing a semiconductor memory module is proposed. A control element is provided. A first branch of a command/address bus connected to the control element and to a first group of memory chips is formed. Further, a second branch of the command/address bus connected to the control element and to a second group of memory chips is formed, wherein one branch connects to a greater quantity of memory chips than the other branch.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention in a non-limiting manner. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a top side view of a semiconductor memory module fitted with DRAMs and a HUB;

FIG. 2 shows a bottom side view of the semiconductor memory module of FIG. 1;

FIG. 3 shows a schematic sectional view along the axis A-A of FIG. 1; and

FIG. 4 illustrates the command/address bus of the left side of the memory module shown in FIG. 1 in a schematic layout.

FIG. 5 shows a computer system according to an embodiment of the present invention.

### DETAILED DESCRIPTION

In the following detailed description reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing” etc., is used with reference to the orientation of the Figures being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense and the scope of the present invention is defined by the appended claims.

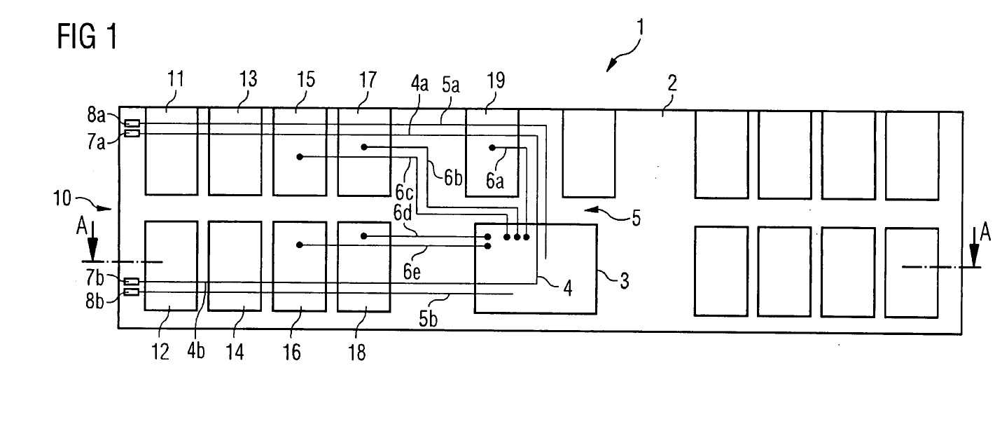

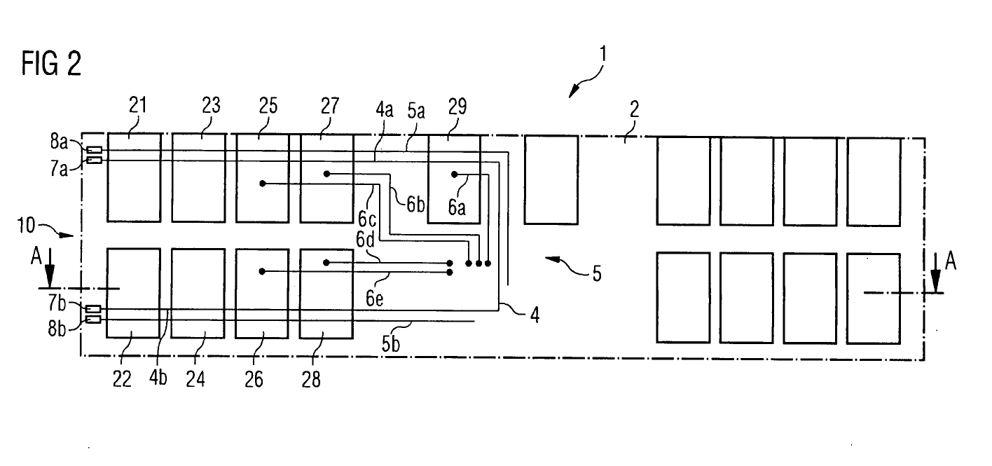

An exemplary embodiment of a semiconductor memory module 1 is shown in an illustrative FIG. 1 which shows the top side of the memory module 1. The underside of the memory module 1 is illustrated in FIG. 2. The illustration of FIG. 2 is not rotated. The view is like one looks through the module from the top. Therefore, the boundary of the memory module 1 is drawn in dashed lines.

The memory module 1 comprises a printed circuit board (PCB) 2 which has typically external and internal layers for signal communication. Arranged at the bottom of the PCB are electrical contacts (not shown for simplicity) that fit to matching memory slots of a mainboard.

The signals communicating to and from the mainboard arrive at a buffer or hub chip 3. The hub chip 3 is implemented for Buffered DIMMs (Double Inline Memory Module) and Fully Buffered (FB-) DIMMs. As to buffered DIMMs, the command/address connections are routed through the hub chip. As to FB-DIMMs, the command/address, clock and data connections are routed through the hub chip. In this specific embodiment a FB-DIMM is considered. Accordingly the hub chip 3 handles command/address, clock and data signals. The hub chip 3 receives serial signals from the chipset located on the mainboard, processes them and puts them out to the module.

The output pins of the hub chip 3 are connected to different buses and connection lines. There is a command/address bus 4 and two clock copy (CLK) buses 5a and 5b. Some data connections 6a, 6b and 6c are shown.

FIGS. 1 and 2 illustrate only connections on the left side of the memory module 1. The right side of the module is wired symmetrically. For reasons of clarity not every data connection 6 is shown. However, each chip is connected with a data connection to the hub chip 3.

Connections and buses as mentioned in the context of this description encompass all direct and indirect links. The connections and buses can be implemented physically and electrically or may only be electrically, e.g. wireless connections. Optical connections are included as well.

Two CLK buses 5 (an upper CLK bus 5a and a lower CLK bus 5b) and one command/address bus 4 are provided on the left side of the memory module 1. The command/address bus 4 comprises an upper branch 4a and a lower branch 4b. In total the memory module 1 comprises two command/address buses (left 4 and right not shown) each having an upper branch and a lower branch as well as four CLK buses. The memory module also comprises two CLK buses (upper CLK bus 5a and a lower CLK bus 5b) are arranged on the left side and two CLK buses (another upper and lower CLK bus, not shown) are arranged on the right side.

In the example shown a plurality of thirty-six memory chips 10 is attached to the memory module 1. Eighteen memory chips are placed on the top surface of the PCB 2 (FIG. 1). In a left part of the top surface memory chips 11, 13, 15 and 17 are arranged in an upper row while memory chips 12, 14, 16 and 18 are arranged in a lower row. In a central area of the top surface the hub chip 3 is arranged at the lower row whereas one memory chip 19 is arranged at the upper row. The memory chip 19 is disposed in a left section of the central area. The memory chip 19 may be an error correction code (ECC) chip. The right part of the memory module has a symmetric layout.

The other eighteen memory chips are placed on the bottom surface of the PCB 2 (FIG. 2). In a left part of the bottom surface memory chips 21, 23, 25 and 27 are arranged in an upper row while memory chips 22, 24, 26 and 28 are arranged in a lower row. In a central area of the surface one memory chip 29 is arranged at the upper row. The memory chip 29 is disposed in a left section of the central part. The memory chip 29 may be an error correction code (ECC) chip. The right part of the memory module has a symmetric layout.

In the following the interaction between the connections and the chips is discussed. The command/address bus 4 comprises an upper branch 4a which connects to the memory chips 11, 13, 15, 17, 19 and 21, 23, 25, 27 and 29. The memory chips 19 and 29 in this specific embodiment are error correction code (ECC) chips. The upper branch 4a of the command/address bus 4 is terminated with a resistor 7a. The lower branch 4b of the command/address bus 4 connects to the memory chips 12, 14, 16, 18 and 22, 24, 25 and 28 and is terminated with a resistor 7b.

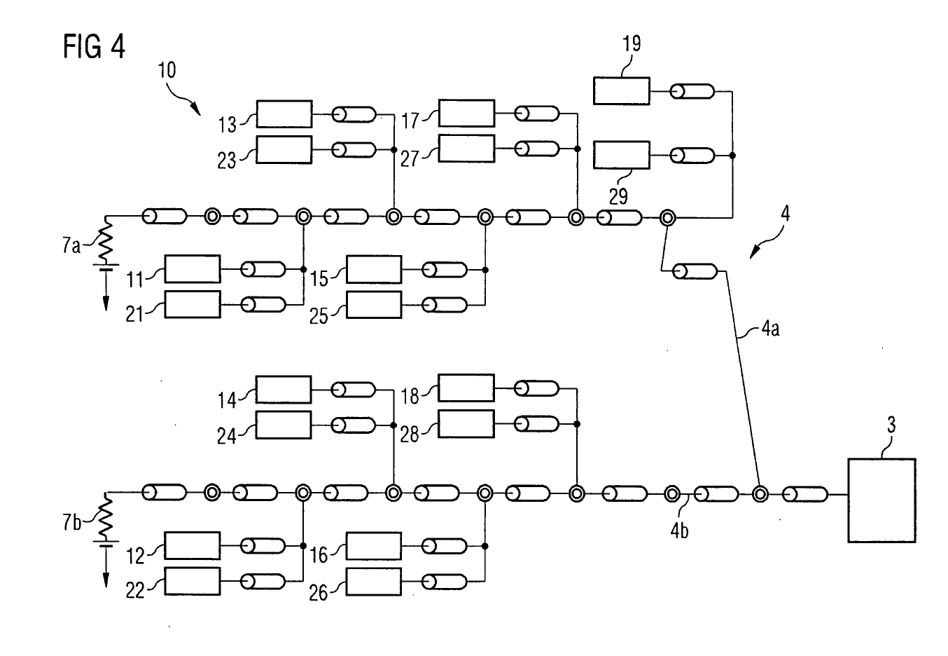

The two branches 4a, 4b of the command/address bus 4 are asymmetric. The upper branch 4a connects to ten loads while the lower branch connects to eight loads. Due to the unbalanced load arrangement on the command/address bus 4 the upper branch 4a is of greater length in this specific embodiment than the lower branch 4b. This embodiment comprises a command/address bus 4 that is asymmetric in at least two respects. First, the loads on the branches of the command/address bus are different. Second, the length of the two branches of the command/address bus 4 is different. However, the length of the lower branch 4b can be adapted to match the length of the upper branch 4a. A more detailed discussion of the command/address bus 4 will follow in conjunction with FIG. 4.

The upper CLK bus 5 connects to the memory chips 11, 13, 15, 17, 19 and 21, 23, 25, 27 and 29 and is terminated with a resistor 8a. The lower CLK bus 5b connects to the memory chips 12, 14, 16, 18 and 22, 24, 25 and 28 and is terminated with a resistor 8b. The upper CLK bus 5a is adapted to match the flight time (i.e. traveling time) of the signals on the upper branch 4a of the command/address bus 4. Usually this is achieved by adjustment of the length of the upper CLK bus 5a. The lower CLK bus 5b is designed to match the flight time of the signals on the lower branch 4b of the command/address bus 4. Usually this is achieved by adjustment of the length of the lower CLK bus 5b. In this embodiment the physical length of the upper CLK bus 5a is greater than the physical length of the lower CLK bus 5b.

The data connections 6 are point to point connections between the hub chip 3 and the memory chips 10 in this embodiment. A bus system or a daisy chain connection can be implemented as well.

As an example the data connections 6a to the ECC chip 19, 6b to the memory chip 17, 6c to the memory chip 15, 6d to the memory chip 18, 6e to the memory chip 16, 6a to the ECC chip 29, 6b to the memory chip 27, 6c to the memory chip 25, 6d to the memory chip 28 and 6e to the memory chip 26 are shown. The remainder of the memory chips 10 is likewise connected by corresponding data connections. Since this exemplary memory module 1 is organized as a 2R×4 DIMM, each Rank contains two memory chips. If for example data connection 6b is activated write or read access is possible to or from memory chips 17 and 27 simultaneously.

The organization of the memory module 1 is not limited to two ranks. A four or eight rank memory module can be implemented as well. Using four ranks a read or write access activates four memory chips at a time, for example memory chips 15, 17, 25 and 27. An organization with eight ranks could be implemented with stacked memory modules. In that case a second layer of memory modules is attached to the memory modules 10 shown in FIGS. 1 and 2. A read or write access activates eight memory chips simultaneously, for example memory chips 15, 17, 25 and 27 and four memory chips (not shown) stacked on top of the memory chips 15, 17, 25 and 27. Designing ranks into the topology according to the present invention it is important that the memory chips organized into one rank are located at a single branch so that the timing requirements are met.

The data connections 6 are designed to match the flight time of the signals on the CLK bus 5. It is not necessary that the flight times match exactly. The requirement CLK/DQ≦400 ps should be met which means that a clock signal (CLK) on the CLK bus and a data signal (DQ) on a data connection should arrive within 400 pico seconds at a memory chip. The flight time is the duration which a signal needs to travel from a starting point (e.g. the hub chip) to an arrival point (e.g. a memory chip).

For this embodiment the adaptation is achieved by variation of length of the specific data connections 6. Another approach would be to integrate a timing logic in the hub chip 3 in order to send leading or lagging signals to specific memory chips.

Looking for example at the memory chips 17 and 18 which are located at more or less the same distance from the hub chip 3 is has to be noted that the data connection 6b to memory chip 17 is longer than the data connection 6d to memory chip 18. In this example, data connection 6b is longer because it has to adapt to the longer flight time of the upper branch 4a of the command/address bus 4. The flight time of the upper branch 4a of the command/address bus 4 is longer since the ECC chip 19 is integrated into the upper branch 4a. The lower branch 4b on the other hand is shorter because of the absence of an ECC chip. The difference in length is usually attained by meandering patterns of the data connection (not shown).

Regarding the buses 4 and 5 and connections 6 one can summarize that due to the asymmetric load of the command/address bus 4 (ten loads at the upper branch 4a and eight loads at the lower branch 4b) the upper CLK bus 5a and the “upper” data connections 6a, 6b and 6c to the memory chips 11, 13, 15, 17, 19 and 21, 23, 25, 27, 29 disposed at the upper rows are longer than the lower CLK bus 5b and the “lower” data connections to the memory chips 12, 14, 16, 18 and 22, 24, 26, 28 disposed at the lower rows.

The memory chips 10 shown in this embodiment are 1 Gb chips and the height of the memory module 1 is more than the standard single height. The height of the module can be 42, 45 or 50 mm. The required height depends on the size of the available memory chips 10.

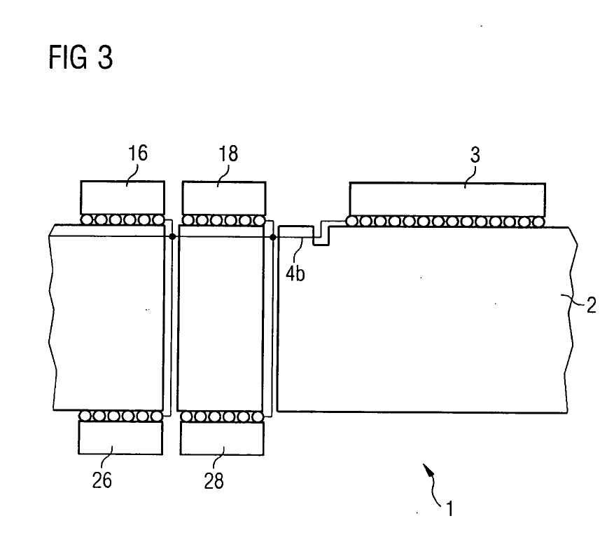

FIG. 3 illustrates a sectional view along the axis A-A of FIG. 1. The memory chips 16, 18, 26 and 28 as well as the hub chip 3 are SBGA (Super Ball Grid Array) chips. The lower branch 4b of the command/address bus 4 is schematically shown connecting from the hub chip 3 to the memory chips 16, 18, 26 and 28. It is shown that the connection to the memory chips 18 and 28 leaves the lower branch 4b at one junction and that the connection to the memory chips 16 and 26 leaves the lower branch 4b at a further junction. Not shown in FIG. 3 are the layers of the PCB 2 which support the connections and buses.

FIG. 4 shows the command/address bus 4 starting from a single pin of hub chip 3 and branching into upper branch 4a which is terminated by resistor 7a and into lower branch 4b which is terminated by resistor 7b. The resistors in the command/address bus 4 are depicted to symbolize the resistances arising from the connection lines and/or contact holes.

The loads (memory chips 10) are unequally distributed as is described above. The upper branch 4a connects to the same amount of memory chips as the lower branch 4b but has two ECC chips 19 and 29 additionally attached. These two ECC chips 19, 29 are disposed at the upper branch 4a in the same manner as the memory chips 10.

This design of the command/address bus 4 integrates an asymmetric layout of the memory chips 10 on the PCB 2 into a functional electrical design. No special stubs to ECC chips are needed. Since this embodiment goes without stubs signal integrity is improved. At the same time it is possible to reduce power consumption because the reduction of reflections allows for a more efficient terminating resistor.

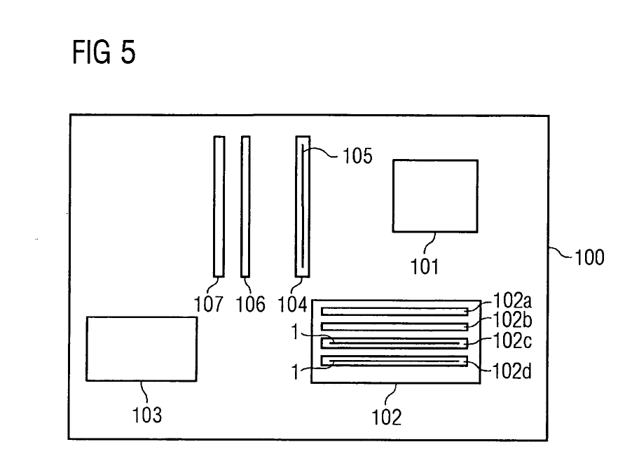

FIG. 5 shows an exemplary computer system 100 which comprises a processor 101, a memory subsystem 102, a data storage 103 (like a hard disk), a slot 104 for a graphics adapter 105 and two further expansion slots 106 and 107. The slots 104, 105 and 107 may be of the same architecture or of different ones. Known architectures include PCI (Peripheral Component Interconnect), AGP (Accelerated Graphics Port) or PCI Express. A chipset (not shown) connects all elements of the mainboard.

The memory subsystem 102 comprises four memory slots 102a, 102b, 102c and 102d. Memory slots 102a and 102b are empty. Memory slots 102c and 102d accommodate memory modules 1 which have been described in detail. Most likely four to sixteen memory slots are provided.

The memory modules 1 are the main memory of the computer system 100. Programs executed on the processor 101 use the memory modules 1 to save and read information to and from the main memory, respectively.

An embodiment of a manufacturing process for the exemplary memory module 1 comprises the following steps which have not to be implemented in the described order. The process of forming a PCB is well known and hence is no need to describe it in this description. The steps to be described need not to be separated steps. Instead one could process parts of different steps together, for example due to restrictions or benefits of the manufacturing process.

Primarily the first branch 4a of the command/address bus 4 is formed to connect a first group of chips 11, 13, 15, 17 and 19 and 21, 23, 25, 27, 29 with the hub chip 3. Then, the second branch 4b of the command/address bus 4 is formed to connect a second group of chips 12, 14, 16 and 18 and 22, 24, 26, 28 with the hub chip 3. The first branch 4a connects to ten memory chips while the second branch 4b connects to less memory chips (eight memory chips).

In this embodiment the physical length of the first branch 4a is longer than that of the second branch 4b due to the additional memory chips. For better signal integrity the CLK buses 5 are designed to match the flight times of the branches 4a, 4b of the command/address bus 4. In this example, the length of the upper CLK bus 5a is adapted so that the signals on the upper branch 4a of the command/address bus 4 and the signals of the upper CLK bus 5a arrive at approximately the same time at a memory chip. The same adaptation is applied for the lower CLK bus 5b and the lower branch 4b. The lower CLK bus 5b is therefore of shorter length than the upper CLK bus 5a.

In a next step the data connections 6 from the hub chip 3 to the memory chips 10 are made. Again, the length of a data connection 6 is adapted to the flight time of a signal on the command/address bus 4 or of a signal on one of the CLK buses 5. Usually the CLK bus 5 is chosen as a reference so that the equation CLK/DQ≦400 ps is satisfied. This means that the delay between a signal on the CLK bus 5 and a signal on the data connection 6 is less than 400 pico seconds.

More steps may follow during the process of manufacturing but are not described in this example since they are well known.

The present invention was described, by way of example, for a FB-DIMM module having thirty-two DDR DRAM chips, four ECC chips and one buffer chip. However, it goes without saying that the principle underlying the present invention is not restricted to DIMM modules having DRAM memories but rather may be used wherever data are written to and read from memory chips in synchronization with a fast clock signal. The present invention can be used in context of any memory module.

Although specific embodiments have been illustrated and described herein it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor memory module comprising:
a plurality of memory chips;
at least one bus connecting said plurality of memory chips;
wherein said bus comprises at least a first and a second branch, wherein said first branch is connected to a greater quantity of memory chips than said second branch.

2. A semiconductor memory module of claim 1, wherein said at least one bus comprises a first command/address bus connected to a first group of said plurality of memory chips and a second command/address bus connected to a second group of said plurality of memory chips; wherein the first and the second command/address buses each comprise two branches.

3. A semiconductor memory module of claim 1, wherein said greater quantity of memory chips are error correction code chips.

4. A semiconductor memory module of claim 1, further comprising a control chip that drives command/address signals to said plurality of memory chips via said at least one bus.

5. A semiconductor memory module of claim 1, further comprising a control chip that drives data signals to and receives data signals from said plurality of memory chips via data connections.

6. A semiconductor memory module of claim 1, further comprising a control chip that drives data signals to and receives data signals from said plurality of memory chips via data connections and that drives command/address signals to said plurality of memory chips via said at least one bus.

7. A semiconductor memory module comprising:
a plurality of memory chips;
at least one command/address bus connected to said plurality of memory chips;
wherein said command/address bus comprises two branches, a first branch connected to a greater quantity of said plurality of memory chips than a second branch, wherein the difference in quantity between said first and second branch are error correction code chips.

8. A semiconductor memory module of claim 7, wherein said command/address bus comprises a first command/address bus connected to a first group of said plurality of memory chips and a second command/address bus connected to a second group of said plurality of memory chips; wherein the first and the second command/address bus each comprise said two branches.

9. A semiconductor memory module comprising:
a printed circuit board comprising a top surface, a bottom surface and a central area, each of said top and bottom surfaces having a left part and a right part adjacent to said central area;
a plurality of memory chips connected to said top and bottom surfaces, wherein said plurality of memory chips is arranged in lower and upper rows each having at least one left section and at least one right section;
error correction code chips connected to said top and bottom surfaces in said central area;
at least one left command/address bus configured on said at least one left section of the printed circuit board connected to the memory chips disposed on said at least one left section and at least one right command/address bus configured on said at least one right section of the printed circuit board connected to the memory chips disposed on the at least one right section;
at least one data connection configured on the at least one left section of the printed circuit board connected to the memory chips disposed thereon and at least one data connection arranged at the at least right section of the printed circuit board connected to the memory chips disposed thereon;
a control chip that drives command/address signals to one of said plurality of memory chips, said error correction code chips and said plurality of memory chips and said error correction code chips via the left and right command/address buses, and drives data signals to and receives data signals from one of said plurality of memory chips, said error correction code chips and said plurality of memory chips and said error correction code chips via the at least one data connection, wherein said control chip is disposed in said central area;
wherein said command/address bus comprises a lower branch and an upper branch, said lower branch connected to the memory chips of the lower rows, said upper branch connected to the memory chips of the upper rows and to said error correction code chips disposed in said central area.

10. A semiconductor memory module of claim 9, wherein said control chip is disposed in the central area in the lower row and wherein said error correction code chips are disposed in the central area in the upper row.

11. A semiconductor memory module of claim 9, wherein at least one data connection connected to the memory chips of the upper rows disposed at the top and the bottom surface matches a flight time of the upper branch of said command/address bus.

12. A semiconductor memory module of claim 9, further comprising at least one clock bus connected to the memory chips of the upper rows disposed at the top and the bottom surface matches a flight time of the upper branch of said command/address bus.

13. A semiconductor memory module of claim 9, wherein said control chip buffers signals for said command/address buses, said clock buses and said data connection.

14. A semiconductor memory module of claim 9, wherein said semiconductor memory module is configured as a dual in-line memory module.

15. A semiconductor memory module of claim 9, wherein said plurality of memory chips are DDR DRAM chips.

16. A semiconductor memory module of claim 9, wherein the height of said semiconductor memory module is greater than 30.35 mm.

17. A semiconductor memory module of claim 9, wherein the height of said semiconductor memory module is 50 mm.

18. A computer system comprising:
a processor;
a memory subsystem, including at least one semiconductor memory module which comprises a plurality of memory chips; at least one bus connecting said plurality of memory chips; wherein said bus comprises at least a first and second branch, wherein said first branch is connected to a greater quantity of memory chips than said second branch.

19. A computer system comprising:
a processor;
a memory subsystem, including at least one semiconductor memory module which comprises a plurality of memory chips; at least one command/address bus connected to said plurality of memory chips; wherein said command/address bus comprises two branches, a first branch connected to a greater quantity of said plurality of memory chips than a second branch, wherein the memory chips connected to said first branch exceeding the memory chips connected to said second branch are error correction code chips.

20. A computer system comprising:
a processor;
a memory subsystem, including at least one semiconductor memory module which comprises a printed circuit board comprising a top surface, a bottom surface and a central area, each of said top and bottom surfaces having a left part and a right part adjacent to said central area;
a plurality of memory chips connected to said top and bottom surfaces, wherein said plurality of memory chips is arranged in lower and upper rows each having at least one left section and at least one right section;
error correction code chips connected to said top and bottom surfaces in said central area;
at least one left command/address bus configured on said at least one left section of the printed circuit board connected to the memory chips disposed on said at least one left section and at least one right command/address bus configured on said at least one right section of the printed circuit board connected to the memory chips disposed on the at least one right section;
at least one data connection configured on the at least one left section of the printed circuit board connected to the memory chips disposed thereon and at least one data connection arranged at the at least right section of the printed circuit board connected to the memory chips disposed thereon;
a control chip that drives command/address signals to one of said plurality of memory chips, said error correction code chips and said plurality of memory chips and said error correction code chips via the left and right command/address buses, and drives data signals to and receives data signals from one of said plurality of memory chips, said error correction code chips and said plurality of memory chips and said error correction code chips via the at least one data connection, wherein said control chip is disposed in said central area;
wherein said command/address bus comprises a lower branch and an upper branch, said lower branch connected to the memory chips of the lower rows, said upper branch connected to the memory chips of the upper rows and to said error correction code chips disposed in said central area.

21. A method of manufacturing a semiconductor memory module, comprising the steps:
providing a control element;
forming a first branch of a command/address bus connected to said control element and to a first group of memory chips;
forming a second branch of the command/address bus connected to said control element and to a second group of memory chips;
wherein one branch connects to a greater quantity of memory chips than the other branch.

22. A method of claim 21, comprising forming at least one data connection connected to said control element and to at least one of the memory chips to match a flight time of a branch of said command/address bus from said control element to said at least one of the memory chips.
